(19) United States
(12) Patent Application Publication
(10) Pub. No.: US 2023/0238328 A1
(43) Pub. Date: Jul. 27, 2023

(54) BAND BEND CONTROLLED TOPOLOGICAL SEMIMETAL DEVICES AND METHODS THEREFOR

(71) Applicant: Alliance for Sustainable Energy, LLC, Golden, CO (US)

(72) Inventors: Kirstin ALBERI, Denver, CO (US); Anthony D. RICE, Denver, CO (US); Brian Darrius FLUEGEL, Golden, CO (US); Choong Hee LEE, Frisco, TX (US)

(21) Appl. No.: 18/099,559

(22) Filed: Jan. 20, 2023

Related U.S. Application Data
(60) Provisional application No. 63/301,748, filed on Jan. 21, 2022.

(51) Int. Cl. H01L 23/532; H01L 31/0216; H01L 29/778

(52) U.S. Cl. CPC H01L 23/53271; H01L 31/02161; H01L 29/7786

(57) ABSTRACT

Described herein are devices and methods that utilize three-dimensional topological semimetals (including Dirac, Weyl and nodal line) that may be useful in advanced electronic devices. The Fermi level in three dimensional topological semimetals can be significantly shifted in energy when forming a heterojunction with a semiconductor or metal. This has unintended and sometimes negative consequences for device performance. Described herein are designs and methods to modify the heterostructures to either suppress Fermi level movement or to produce an intentional shift to allow for the use of these improved semimetal devices.

### CROSS-REFERENCE TO RELATED APPLICATIONS

This application claims priority from U.S. Provisional Patent Application No. 63/301,748 filed on Jan. 21, 2022, the contents of which are incorporated herein by reference in their entirety.

### CONTRACTUAL ORIGIN

This invention was made with government support under Contract No. DE-AC36-08G028308 awarded by the Department of Energy. The government has certain rights in the invention.

### SUMMARY

Described herein are devices and methods that utilize three-dimensional topological semimetals (including Dirac, Weyl and nodal line) that may be useful in advanced electronic devices. The Fermi level in three dimensional topological semimetals can be significantly shifted in energy when forming a heterojunction with a semiconductor or metal. This has unintended and sometimes negative consequences for device performance. Described herein are designs and methods to modify the heterostructures to either suppress Fermi level movement or to produce an intentional shift to allow for the use of topological semimetal-based devices.

In an aspect, provided is a device comprising: a) a Dirac, Weyl or nodal line topological semimetal layer; b) a dielectric layer proximate to the semimetal layer; c) a metal layer or semiconductor layer proximate to the dielectric layer. The device may further comprise a substrate proximate to the semimetal layer or the metal layer. For example, the use of a semiconductor may be useful in photodetector devices, while the use of a metal layer may be useful in transistors. Advantageously, the topological semimetals can cover a greater wavelength range and can be grown on conventional, large area GaAs (001) substrates. Additionally, for transistors the ultra-fast electron mobility found in the semimetals may improve performance.

Examples of Dirac, Weyl or nodal line semimetals include Cd₃As₂, Na₃Bi, WTe₂, NbAs, TaAs, TaP, NbP, ZrTe₅, PtSe₂, α-Sn and/or combinations thereof. Examples of dielectric layers include CdTe, ZnTe, ZnₓCd₁₋ₓTe, Al₂O₃, a III-V semiconductor, a II-VI semiconductor, an oxide, a nitride, a silicide and/or combinations thereof. The dielectric layer may be undoped.

A semiconductor layer may be proximate to the dielectric layer to form a photodetector. The semiconductor layer may comprise, for example, Zn₃As₂, Si, GaSb, GaAs and/or a combination thereof. The semiconductor layer may be doped, including n-type or p-type. The described device may include one or more electrical contacts.

The described device may further comprise a metal layer proximate to the dielectric layer in order to form a transistor. The metal may comprise Ti, Pt, Pd, Ag, Au, Al, In, Ni, W, Mo, Cu, Co and any alloys or combinations thereof. Example alloys include the provided metals alloyed with Si, Ge, Sb, N or a combination thereof. The metal layer may induce band bending, a shift in the Fermi level and doping in the semimetal or dielectric layer.

In an aspect, provided is a photodetector comprising: a semimetal layer comprising: a) a Dirac, Weyl or nodal line topological semimetal selected from the group consisting of: Cd₃As₂, Na₃Bi, NbAs, WTe₂, TaAs, TaP, ZrTe₅, NbP and a combination thereof b) an undoped dielectric layer proximate to the semimetal layer; and c) a doped semiconductor layer proximate to the dielectric layer; wherein the semimetal layer, the dielectric layer and/or the semiconductor layer are epitaxially integrated.

In an aspect, provided is a transistor comprising: a) a semimetal layer comprising a Dirac, Weyl or nodal line topological semimetal selected from the group consisting of: Cd₃As₂, Na₃Bi, NbAs, WTe₂, TaAs, TaP, ZrTe₅, NbP and a combination thereof b) an undoped dielectric layer proximate to the semimetal layer; and c) a metal layer comprising at least one metal proximate to the dielectric layer; wherein the semimetal layer, the dielectric layer and/or the metal layer are epitaxially integrated.

In an aspect, provided is a method comprising: a) providing a Dirac, Weyl or nodal line topological semimetal layer substrate; b) growing a dielectric or semiconductor layer on a surface on the semimetal layer. The step of growing a dielectric or semiconductor layer is performed via molecular beam epitaxy, chemical vapor deposition, sputtering, atomic layer deposition, thermal deposition or other known methods.

The semimetal layer may comprise a III-V semiconductor, a II-VI semiconductor, a IV semiconductor, Cd₃P₃, Zn₃P₃, Cd₃As₂, Na₃Bi, NbAs, WTe₂, TaAs, TaP, ZrTe₅, NbP or a combination thereof. The dielectric or semiconductor layer may comprise CdTe, ZnTe, ZnₓCd₁₋ₓTe, Al₂O₃, a III-V semiconductor, a II-VI semiconductor, an oxide, a nitride, a silicide or a combination thereof. The method may further comprise growing the Dirac, Weyl or nodal line topological semimetal layer on a GaAs, Si, Ge, GaSb, InSb, InAs, or InP substrate.

As used herein, combination thereof may refer to separate, distinct layer or alloys of the various metal components.

### BRIEF DESCRIPTION OF DRAWINGS

Some embodiments are illustrated in referenced figures of the drawings. It is intended that the embodiments and figures disclosed herein are to be considered illustrative rather than limiting.

FIG. 1 illustrates an exemplary device schematic of a photodetector utilizing a topological semimetal layer, according to some embodiments of the present disclosure.

FIG. 2 illustrates an exemplary device schematic of a transistor utilizing a topological semimetal layer, according to some embodiments of the present disclosure.

FIGS. 3A-3C illustrate how band bending in a topological semimetal dielectric metal junction changes with metal selection. Cd₃As₂ is used as the semimetal and CdTe is used as the dielectric for this example. FIG. 3A shows band alignment and representative Fermi level of the Cd₃As₂ CdTe heterostructure. FIG. 3B shows band alignment and Fermi level when a metal with a low work function is added, creating a high electron concentration in the Cd₃As₂ layer at the CdTe interface. FIG. 3C shows band alignment and Fermi level when a metal with a high work function is added, creating a high hole concentration in the Cd₃As₂ layer at the CdTe interface. Note, the Fermi level in the as-grown Cd₃As₂ can vary greatly depending on the doping, up to several hundred meV above or below the Dirac point.

FIGS. 4A-4D illustrate a semimetal p-B-n barrier photodiode. N-type Cd₃As₂ is used as the semimetal, CdTe is used as the undoped barrier, and Zn₃As₂ is used as the p-type semiconductor in this case. FIG. 4A is a basic heterostructure schematic. FIG. 4B shows band alignment under flat band conditions. FIG. 4C shows band alignment and Fermi level when a forward bias is applied. FIG. 4D shows band alignment and Fermi level with a reverse bias is applied.

FIGS. 5A-5F illustrate transistor device designs utilizing metal selection to modulate doping in the semimetal layer. Cd₃As₂ is used as the semimetal for this example. FIG. 5A shows a lateral p-n diode created by utilizing metals with high and low workfunctions to change the doping concentration and type locally in the semimetal FIG. 5B, an N-MOS structure and FIG. 5C, a P-MOS structure formed by selecting the metal work function to modify the doping in the channel. These basic structures can be used to make FIG. 5D rectifier, FIG. 5E logic device and FIG. 5F Ring-oscillator structures.

FIGS. 6A-6D illustrate Cd₃As₂ epitaxy in the (001) orientation. FIG. 6A shows XRD spectrum of a Cd₃As₂/ZnCdTe/ZnTe/GaAs substrate structure. FIG. 6B is an AFM image, FIG. 6C illustrates variable temperature electron concentration and mobility and FIG. 6D provides a TEM image of the same structure.

FIGS. 7A-7F illustrate CdTe heteroepitaxy on Cd₃As₂. FIG. 7A shows XRD spectrum and FIG. 7B shows an AFM image of a CdTe/Cd₃As₂/ZnTe/GaAs sample grown in the (111) orientation. FIG. 7C shows XRD spectrum and FIG. 7D shows AFM image of a CdTe/Cd₃As₂/ZnTe/GaAs sample grown in the (001) orientation. FIG. 7E is a TEM image of the CdTe/Cd₃As₂ interface grown in the (001) orientation. FIG. 7F is FFTs obtained from the Cd₃As₂ and CdTe regions in FIG. 7E.

FIGS. 8A-8G illustrate vertical p-B-n barrier photodiode operational principles and performance. FIG. 8A shows flat band alignment of Cd₃As₂/CdTe/Zn₃As₂ heterostructure. FIG. 8B shows band alignment under forward bias. FIG. 8C shows band alignment under reverse bias. FIG. 8D provides a top down optical micrograph and 3D schematic of experimental photodiode. FIG. 8E is dark and light IV curves measured under different wavelengths (constant power at 1 mW). FIG. 8F is dark and light IV curves measured under 900 nm photon irradiation with varying laser powers. FIG. 8G shows photoresponse of the photodiode at 900 nm.

FIGS. 9A-9D illustrate vertical MIS photodiode operational principles and performance. FIG. 9A is a comparison of the dark IV curves of the MIS and p-B-n diode structures. Schematic band alignments of the MIS Cd₃As₂/CdTe/Au heterostructure under FIG. 9B, V=0. FIG. 9C, V<0 and FIG. 9D, V>0 applied bias.

### REFERENCE NUMERALS

100 Photodetector device
110 Topological semimetal layer
120 Dielectric layer
130 Semiconductor layer
140 Electrical contact
200 Transistor device
210 Metal layer
220 Substrate

### DETAILED DESCRIPTION

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

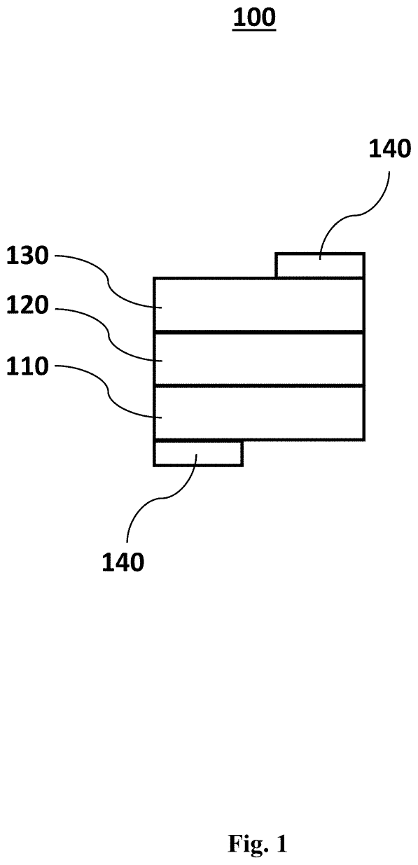

FIG. 1 provides a schematic of a photodetector device 100 as described herein. The bottom layer is a Dirac, Weyl or nodal line topological semimetal layer 110, the middle layer is a dielectric layer 120 and the top layer is a semiconductor layer 130. Each of the described layers (100, 120, 130) may be epitaxially integrated. The device may also include one or more electrical contacts 140.

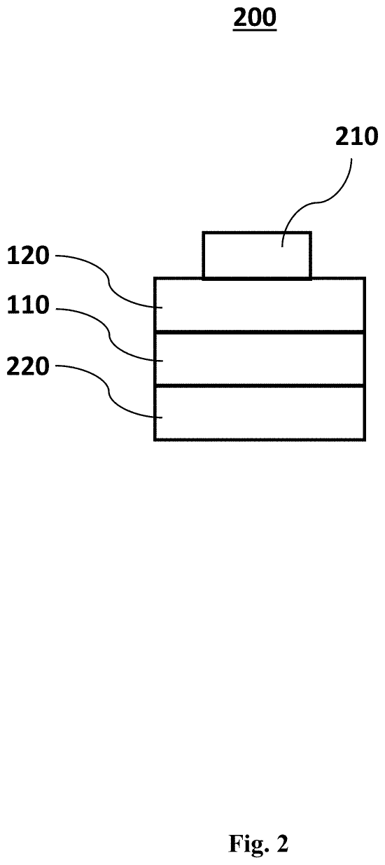

FIG. 2 provides a schematic of a transistor device 200 as described herein. The first layer is a substrate 220, the second layer is a Dirac, Weyl or nodal line topological semimetal layer 110, the third layer is a dielectric layer 120 and the fourth layer is a metal layer 210. Each of the described layers (100, 120, 210, 220).

The provided discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

Three dimensional topological semimetals are promising for a wide range of technological applications. The sub-categories of Dirac and Weyl semimetals are characterized by linear band touching nodes (also termed Dirac points) near the Fermi level. Typical properties include ultra-high electron and hole mobilities and broadband absorption. Those properties are advantageous for transistors, photodetectors and thermoelectrics. Weyl semimetals have the additional feature that their Dirac points are separated in k-space and are thus able to support non-equilibrium populations of electrons or holes with predominantly a single spin direction. Dirac semimetals may do the same if subjected to a magnetic field. This property makes topological semimetals attractive for spintronic applications.

A major challenge of implementing topological materials in these applications has been to make electrical junctions that behave similarly to semiconductor-based junctions. This includes strong rectification across a wide range of applied voltages. Such junctions are the primary enabling feature of semiconductor-based optoelectronic devices. A challenge with utilizing topological semimetals in rectifying junctions is that the density of states is low near the Dirac point, and an applied bias is capable of moving the Fermi level over a greater energy range than in conventional semiconductors. This has the effect of changing an n-type semimetal (high electron concentration) to a p-type semimetal (high hole concentration), and vice versa. The result is non-ideal device behavior compared to semiconductor-based counterparts. Therefore, semimetal-based junctions must be designed with this factor in mind.

Two factors that should be considered when designing a semimetal-based device are:
1. The Fermi levels of all electronic materials included in the junction must align. Fermi level alignment can lead to band bending and changes in carrier concentration at interfaces within the junction as the Fermi level changes its position with respect to the bands during alignment. The flat band alignment of the materials in the junction must be considered in the junction design.
2. The amount of voltage drop across any material in a junction under applied bias depends on its density of states near the Fermi level, its doping concentration and type, its dielectric constant and its thickness.

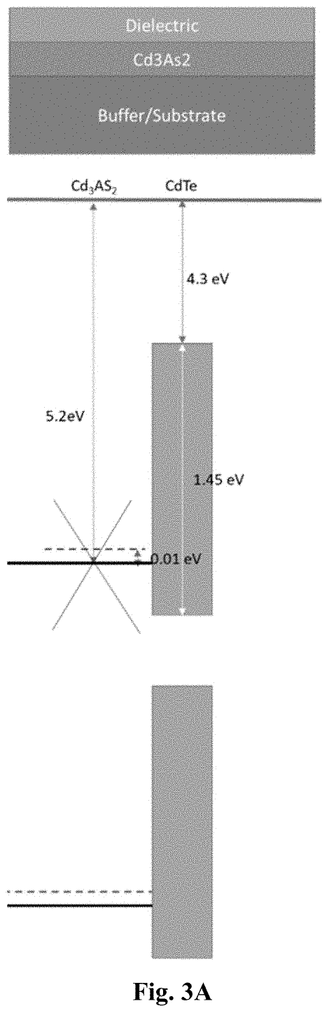

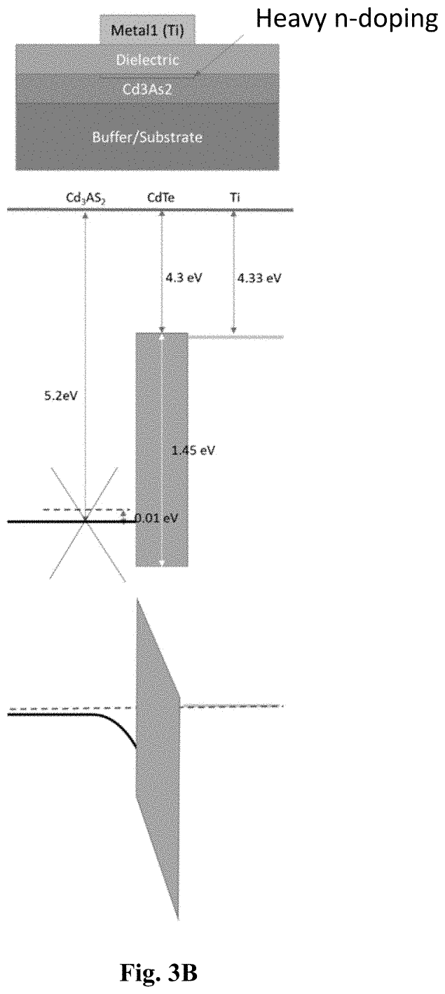

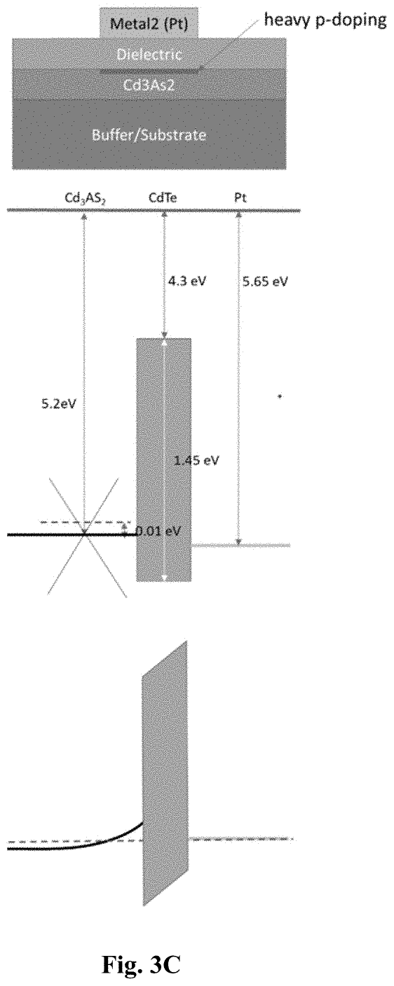

The effect of these factors on band bending in topological semimetals is illustrated in FIG. 3A, using Dirac semimetal Cd₃As₂ as an example. As-grown Cd₃As₂ materials are typically n-type (electron concentrations 1E17 to 1E18 cm⁻³). The energetic position of its Dirac point and the Fermi level when a junction is formed with a thin layer of CdTe (used here as an example of a thin dielectric layer, although the situation would be similar for other dielectric materials) is shown in FIG. 3A. No band bending is expected under thermal equilibrium. However, significant band bending can be introduced into the Cd₃As₂ near the CdTe interface when a metal or semiconducting layer are deposited on top.

FIG. 3B shows the band diagram when the metal layer consists of Ti (work function=4.33 eV). A large portion of the built-in potential over the heterojunction drops across the CdTe layer, bending the conduction and valence bands. A smaller portion of the built-in potential also drops across the Cd₃As₂ layer, producing a small Fermi level shift near the CdTe interface. Because of the small density of states in the Cd₃As₂ layer near the Dirac point, the built-in potential drop substantially shifts the Fermi level position and creates a large electron density in the Cd₃As₂ layer.

Likewise, free hole carriers can be confined at the Cd₃As₂/CdTe interface when a large work function metal is used instead, such as Pt or Au. FIG. 3C shows that a two-dimensional hole gas can be formed within the Cd₃As₂ layer at the CdTe interface in this situation. This mechanism to manipulate the carrier type and concentration is similar to that found in silicon metal-oxide-semiconductor (MOS) structures. A difference is that traditional semiconductors with non-zero bandgaps typically are not capable of switching between high electron and hole concentrations based on the work function of the metal because their density of states is too high for the Fermi level to change over such a wide energy range as in topological semimetals.

Taking this behavior into account, new junctions can be designed to produce high-performance devices. Two generalized design approaches that utilize junction design to control band bending in the semimetal are detailed below. Specific instances of device designs utilize the Dirac semimetal Cd₃As₂, however these devices may be implemented with other topological semimetal materials.

### Photodetectors

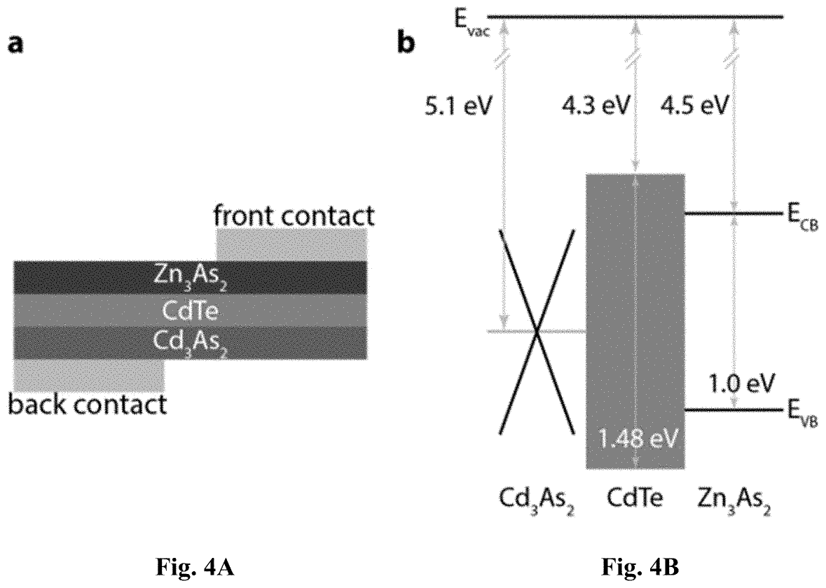

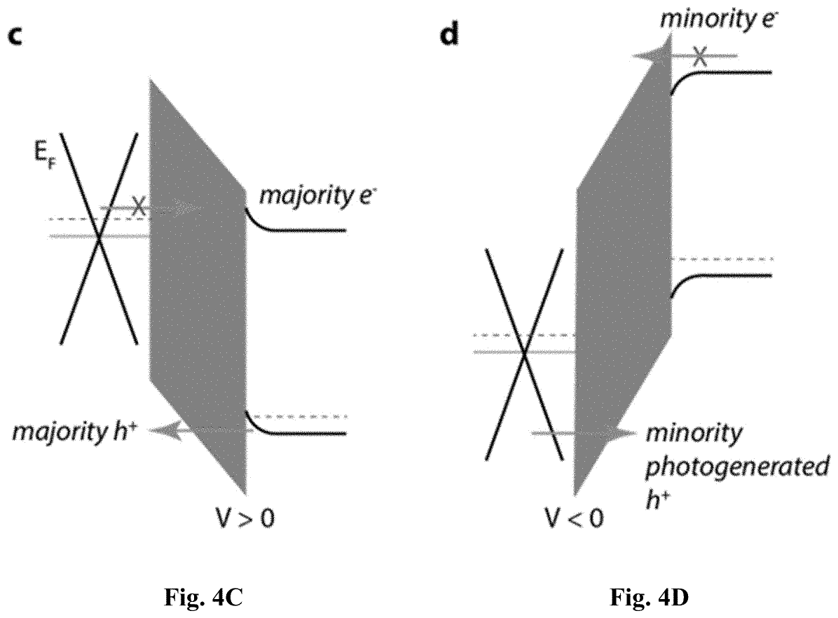

An aspect of the present disclosure is a barrier-type junction that is specifically designed to limit band bending in the semimetal layer. An example is shown schematically in FIGS. 4A-D. It consists of a light-absorbing semimetal (moderately doped) undoped semiconductor low-moderately doped semiconductor. The photodetector is intended to be operated in reverse bias (by applying a negative voltage of several volts). When no light is incident on the photodetector, ideally no current flows (i.e., it has a low “dark current”), and when light absorbed by the semimetal, a non-zero current flows (i.e. a photocurrent).

The thin undoped semiconductor is designed to act as the barrier and pass only photogenerated minority carriers from the semimetal to the low-moderately doped semiconductor. The low-moderately doped semiconductor has two functions: 1) pass the collected minority carriers to the metal contact and 2) allow some of the negative applied voltage to drop across it. This second point is key to the performance of the device. If it was not present (as in the examples shown in FIGS. 3A-3C, where a metal was placed on the other side of the undoped semiconductor), some of the applied voltage would drop across the semimetal, altering the position of the Fermi level relative to the Dirac point. An end effect would be to switch the carrier concentration at the semimetal undoped semiconductor interface from a minority to a majority carrier type, which will produce a high dark current under reverse bias. The inclusion of the low-moderately doped semiconductor absorbs some of the voltage drop, preventing much (if any) from dropping across the semimetal and keeping the dark current low.

A specific instance of such a photodetector design is an Au n-type Cd₃As₂ semimetal undoped (Zn,Cd)Te semiconductor p-type Zn₃As₂ semiconductor Au device, show in FIG. 4A. It exhibits strong rectification and low dark currents when operated in reverse bias (<−4 V). Other instances of barrier type junctions (n-B-n, p-B-n, etc.) could also be implemented for semimetal photodetectors with this design criteria in mind.

### Transistors

Another aspect of the present disclosure in which band bending control is utilized is in high-speed semimetal-based transistors. Transistors require local doping of the semiconductor or semimetal to operate. By selecting the metals with large or small work functions, the metal can impart band bending in the semimetal to make it either n-type or p-type. The basic concept is presented here using Cd₃As₂ as an example.

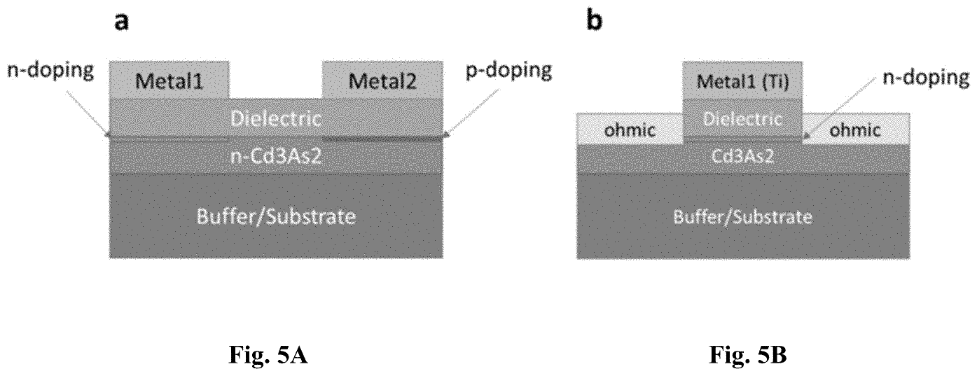

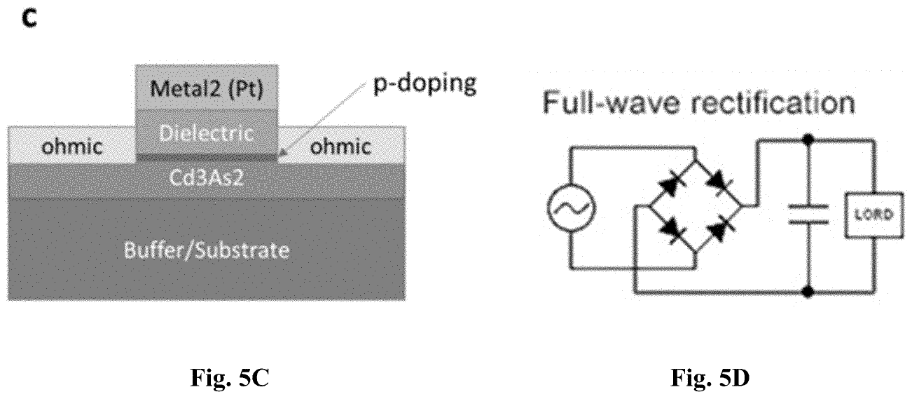

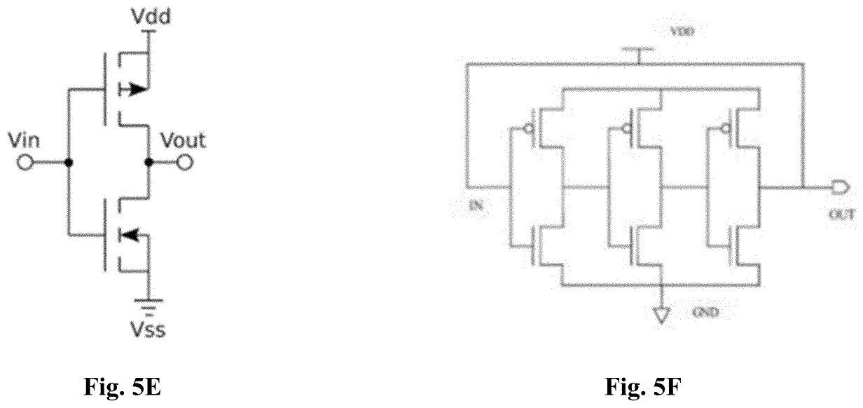

FIGS. 5A-5C show schematic illustration of examples of common transistor structures. Instead of locally doping the semimetal n-type or p-type with extrinsic dopant atoms, only the metal material is selected for its work function to create an n-type or p-type region in the semimetal. For instance, FIG. 5A shows an instance of forming lateral p-n diode by selecting a low workfunction metal to form the n-type region and a high workfunction metal to form the p-type region. FIGS. 5B and 5C illustrate N-MOS and P-MOS device structures through similar design principles. Some widely used circuit applications composed of the combination of diodes, N-MOS, and P-MOS are listed in FIGS. 5D-5F, which are a rectifier, a logic device, and a Ring-oscillator, respectively. All these micro-electronic devices could be demonstrated with the high mobility epitaxially grown Cd₃As₂ material, but the use of other topological semimetals is also possible.

### Example 1—Epitaxial Dirac Semimetal Vertical Heterostructures

### Abstract

Three dimensional topological semimetals exhibit extraordinary transport and optical properties that are useful to a range of applications. Exploiting those properties in high-performance devices will require epitaxial integration into semiconductor heterostructures to carefully control carrier transport, yet challenges exist for growing semiconductors on these materials. Here, we demonstrate the incorporation of Dirac semimetal Cd₃As₂ into semiconductor heterostructures grown on large area GaAs (001) substrates by selecting the materials and crystallographic orientations to overcome growth temperature and surface energy mismatches. We further show that this ability to embed Cd₃As₂ into rationally designed heterostructures can unlock new routes to advancing device performance. As an example, Cd₃As₂ absorbers are introduced into all-epitaxial barrier-type vertical photodetectors that exhibit significantly reduced dark current compared to previously demonstrated non-epitaxial junctions. This performance improvement is only possible with the ability to integrate materials selected for their band alignments across high-quality interfaces. This approach can be extended to other applications in which more sophisticated device architectures will enable the use of topological semimetals for superior performance and compatibility with conventional manufacturing methods.

The entanglement and topological properties found in quantum materials have the potential to revolutionize optoelectronic technologies. A critical next step is to develop devices to harness those properties. Decades ago, when semiconductors faced a similar juncture, heterostructures provided a path to controlling electrical potential, current, carrier concentrations and spin. The conceptualization and initial demonstration of semiconductor heterostructures eventually earned the 2000 Nobel Prize in Physics. Heterostructures will again play an important role in quantum materials-based devices if they can be properly designed and synthesized. To this end, epitaxial integration of quantum materials with semiconductors is necessary for achieving the same control but has largely not been exploited or developed to date.

Three dimensional (3D) topological semimetals are an excellent example of quantum materials that will benefit from epitaxial heterostructures to realize innovative device architectures. Dirac and Weyl semimetals are characterized by the existence of bulk and surface states with linear band dispersions that touch near the Fermi level. Such electronic structures support high electron mobilities, ultra-fast carrier recombination times and strong broadband absorption that are advantageous for high-speed transistors, photodetectors and thermoelectrics. The opposite chirality of Weyl nodes in cases where inversion or time reversal symmetry is broken can also benefit spintronic applications. Simple devices, ranging from metal contacts deposited on bulk crystals or nanostructures to oxide, polymer or 2D layer deposited on a single epitaxial semimetal layer, have already been demonstrated for a small subset of topological semimetals, including Cd₃As₂ and TaAs. However, these basic device geometries do not impart the functionality and charge control achieved in semiconductor devices. For example, the dark currents remain high in semimetal photodetectors, making them difficult to operate in reverse bias. Improved current control requires advanced device designs borrowed from conventional photodetectors that utilize vertical architectures in which monolithic growth does not end at the semimetal.

Described herein is epitaxial growth of CdTe/Cd₃As₂/(Zn,Cd)Te double heterostructures on GaAs (001) substrates by molecular beam epitaxy (MBE). We show that selection of the Cd₃As₂ crystallographic orientation is a useful tool for controlling the quality of the top CdTe layer. As proof that such heteroepitaxial structures can immediately enhance device operation, we present a Cd₃As₂-based vertical p-B-n (p-type contact/Barrier/n-type light absorber) barrier photodiode. This epitaxial heterostructure design confers additional carrier transport control not available in the simple metal-insulator-semimetal or Schottky junctions demonstrated to date. Our results provide a blueprint for building a wide array of vertical topological semimetal devices with high quality epitaxial materials and interfaces.

Heteroepitaxy on Cd₃As₂

Cd₃As₂ is one of the most studied 3D topological semimetal material systems. Early investigations of its properties were performed on bulk crystals and nanostructures, but recent success in epitaxially growth on a variety of substrates, including GaSb, GaAs, CdTe and mica, has opened the door for scalably fabricating devices. Cd₃As₂ has a tetragonal crystal structure, and the best epitaxy has been achieved by aligning its lowest energy (112) surface to the (111) surface of zinc blende semiconductors.

It is well known that material A can grow via a two-dimensional (2D) layer-by-layer mode on material B if the surface energy of A is lower. By the same argument, material B then will not readily grow on material A in a 2D mode, and the resulting 3D growth modes can introduce defects and even inhibit conformal double heterostructure formation. This complication is typically addressed in semiconductor heterostructures by reducing the growth temperature to kinetically limit adatom mobility and suppress 3D islanding or using surfactants to alter the surface energy. However, several factors restrict the use of these approaches for growth on Cd₃As₂. The multitude of mismatches in crystal structure, surface energy, lattice constant and bonding environments between Cd₃As₂ and conventional semiconductors can further promote 3D growth. Additionally, the high vapor pressure of Cd₃As₂ requires growth temperatures below 200° C., limiting the use of temperature and surfactants to control growth mode.

Described herein is a different approach to promoting layer-by-layer growth of semiconductors on Cd₃As₂: selecting the crystallographic orientation to reduce the surface energy mismatch. By accessing the higher energy Cd₃As₂ (001) surface, in order to reduce the surface energy mismatch with many zinc blende semiconductors and stabilize layer-by-layer growth on Cd₃As₂, without having to modify the temperature. Growing crystals on their higher energy surfaces typically introduces defects by promoting 3D growth. Yet, as we show herein, the topological nature of Dirac and Weyl semimetals reduces the impact of defects on their room temperature transport, making this strategy more acceptable for these materials.

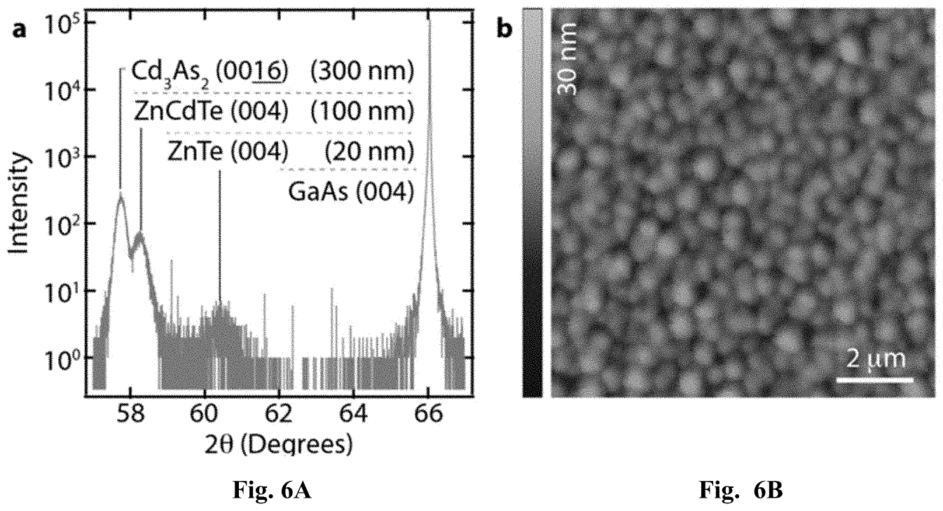

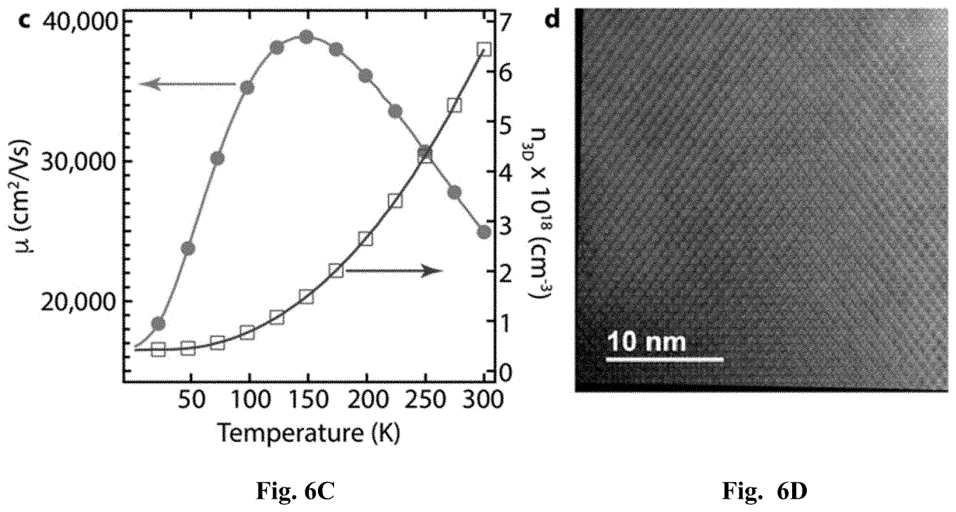

(001) oriented Cd₃As₂ growth was previously reported on GaSb (001) substrates, although its higher surface energy required an InAs wetting layer for improved nucleation. The high temperatures required for III-V materials are also prohibitive for growth on Cd₃As₂. Instead, we form the heterostructure with ZnₓCd₁₋ₓTe. It is lattice-matched to Cd₃As₂ at x=0.42 and can be grown directly on GaAs (111) and GaAs (001) as a buffer to mediate strain relaxation prior to Cd₃As₂ growth (FIG. 6A). Thus, ZnₓCd₁₋ₓTe provides a bridge to integrating Cd₃As₂ into devices fabricated on large area GaAs substrates, and it has a bandgap that is large enough to effectively isolate electrical transport within the Cd₃As₂ epilayer. CdTe can additionally be grown at low temperatures, making it a good match for heteroepitaxy on Cd₃As₂.

In order to implement this integration approach is that Cd₃As₂ must be epitaxially grown in the higher energy (001) orientation without loss of material quality compared to (112) oriented layers. Reflection high energy electron diffraction patterns measured during Cd₃As₂ growth by MBE on nearly lattice-matched ZnCdTe/GaAs (001) structures indicate that nucleation occurs via 3D islanding. X-ray diffraction (XRD) measurements (FIG. 6A) confirm that the Cd₃As₂ epilayers are also oriented in the (001) direction. The resulting morphology (FIG. 6B) resembles coalesced spheres and is similar to a previous report of Cd₃As₂ (001) growth on GaSb substrates. However, the room temperature electron mobilities of our Cd₃As₂ bulk epilayers (˜300 nm thick) are nearly 25,000 cm²/Vs and are comparable to the highest reported values of (112) oriented as-grown Cd₃As₂ epilayers (FIG. 6C). Variable temperature measurements show that the electron mobility increases to above 38,000 cm²/Vs around 150 K before decreasing at lower temperatures. This temperature dependence is similar unpassivated bulk Cd₃As₂ (112) epilayers grown on GaAs substrates. Transmission electron microscopy (TEM) images (FIG. 6D) otherwise confirm that the bulk Cd₃As₂ (001) epilayers are of high quality.

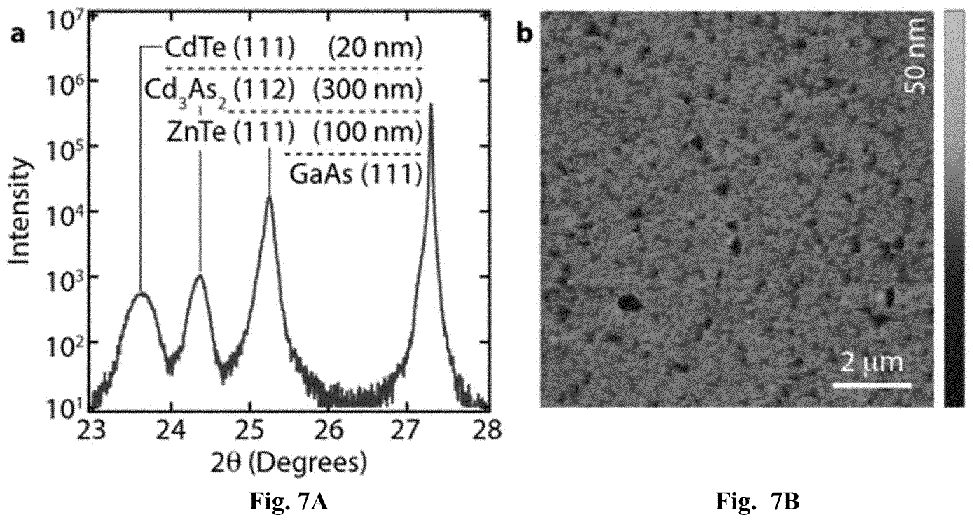

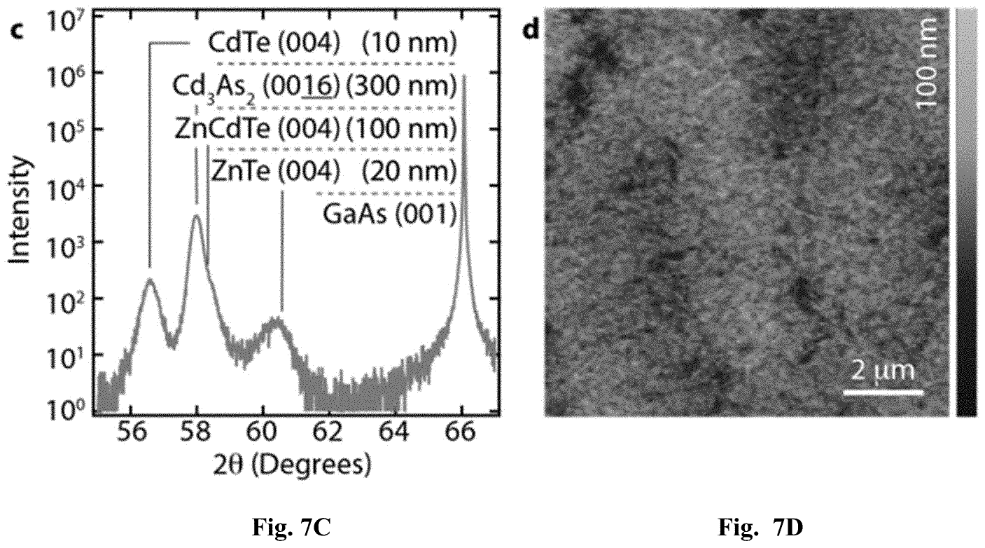

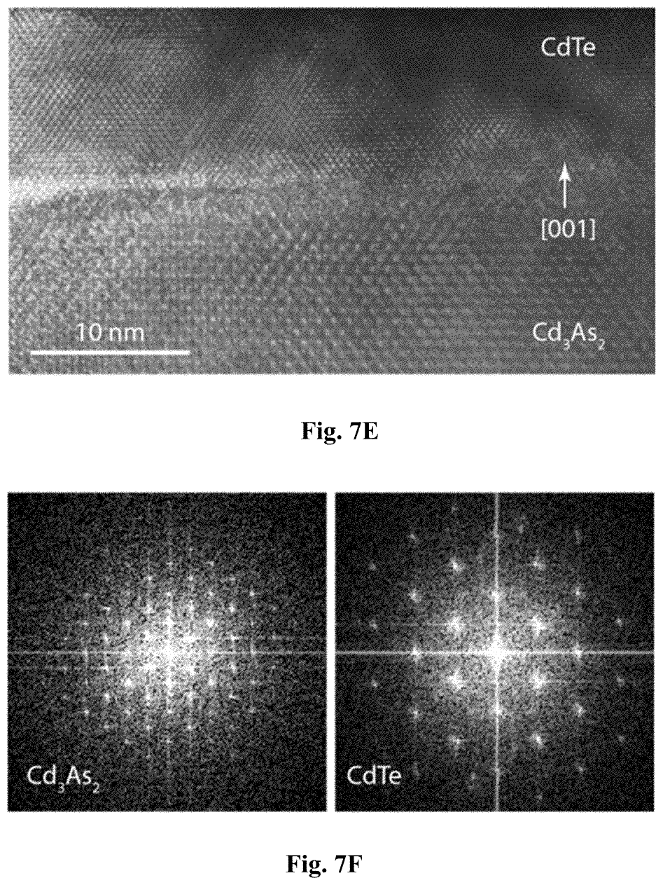

To demonstrate semiconductor epitaxy on Cd₃As₂, we selected CdTe instead of a ZnₓCd₁₋ₓTe alloy to distinguish this layer in XRD. Despite having a rougher surface, Cd₃As₂ (001) is much better at promoting subsequent conformal CdTe heteroepitaxy than Cd₃As₂ (112). XRD measurements (FIG. 7A) indicate that CdTe (111) grows on Cd₃As₂ (112), but atomic force microscopy (AFM) (FIG. 7B) reveals a high density of pinholes in the CdTe layer, even for a 20 nm thick film. Similar 10 nm thick CdTe (001) epilayers grown on Cd₃As₂ (001) are also well-defined according to XRD (FIG. 7C), but now show no evidence of the sharply defined pinholes observed in the (111) epilayers (FIG. 7D). TEM images of the CdTe/Cd₃As₂ (001) heterostructure and their fast Fourier transforms (FFTs) reveal highly crystalline layers on either side of an abrupt interface and no evidence of voids or pinholes (FIGS. 7E-7F). These results can be explained in the context of surface energy differences between Cd₃As₂ and CdTe in these two orientations, where the higher energy Cd₃As₂ (001) surfaces stabilize 2D growth of pinhole-free CdTe at thicknesses below 10 nm. An added benefit is that this orientation is more compatible with existing device manufacturing.

### Vertical Photodetector

The ability to integrate Cd₃As₂ into vertical heterostructures on large area substrates opens the door to realizing a wide range of device designs. To illustrate how our heteroepitaxial growth approach might be used in such ways, we demonstrate an epitaxial vertical photodetector. The appeal of using Cd₃As₂ is that the Dirac band touching nodes allow for broadband light absorption, while its 3D structure enhances light absorption efficiency well beyond single layer graphene. The ultra-short carrier recombination times (ps) and high electron mobilities supported by Cd₃As₂ also hold promise for fast photodetector response. The main challenge has been to implement a device design that can take full advantage of these properties. Initial photodetectors were demonstrated in simple metal-Cd₃As₂ nanostructure-metal structures that principally operate through the photothermoelectric effect. More recently, detectors fabricated from Cd₃As₂-organic, 2D and oxide junctions have been reported but exhibit weak rectification. Notably, none of these designs allow the photodetector to be operated in reverse bias with low dark currents, as is possible in state-of-the-art p-i-n and barrier semiconductor devices. Combining dark current control with the elegance of vertical carrier separation requires heterojunctions designed to prevent majority carrier flow. As found in the case of graphene, creating a p-n junction directly from a semimetal is difficult, and Schottky junctions are often used. Alternative device designs are needed to further improve semimetal-based photodetector performance.

Building on the heteroepitaxial growth capabilities described herein, we demonstrate a vertical photodetector design that enables carrier separation via a barrier type p-B-n operating principle. Barrier device structures, used in HgCdTe photodetectors today, manage dark current by introducing a high energy barrier to majority carrier flow from the light absorbing layer. The barrier layer simultaneously presents little obstacle to minority carrier flow in reverse bias. This approach is only possible with the ability to integrate materials selected for their band alignments across high-quality interfaces.

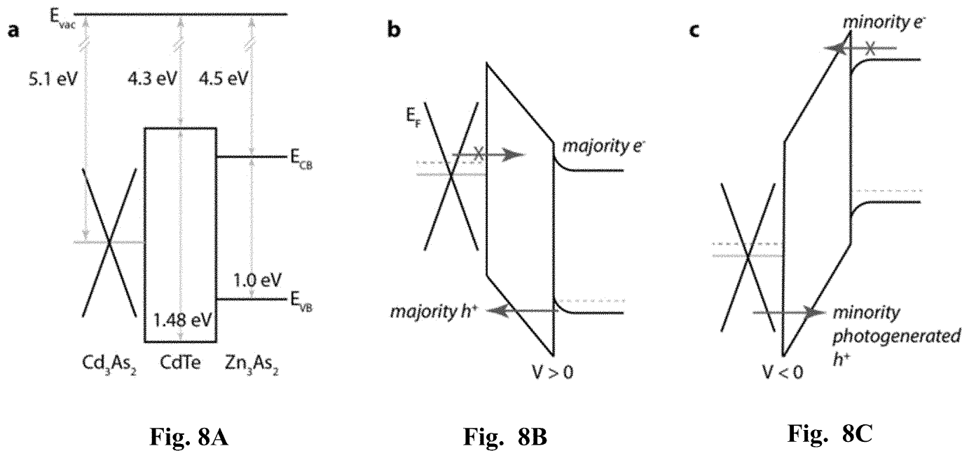

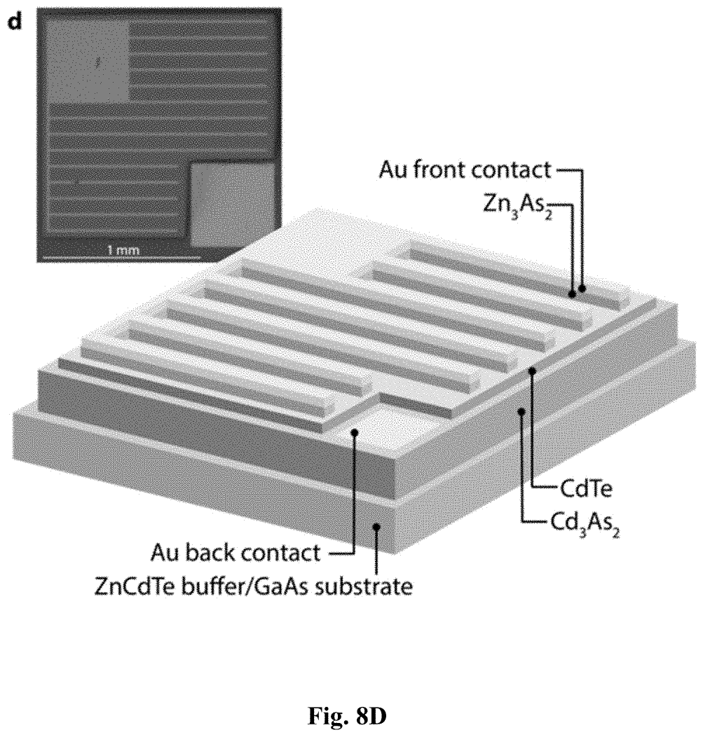

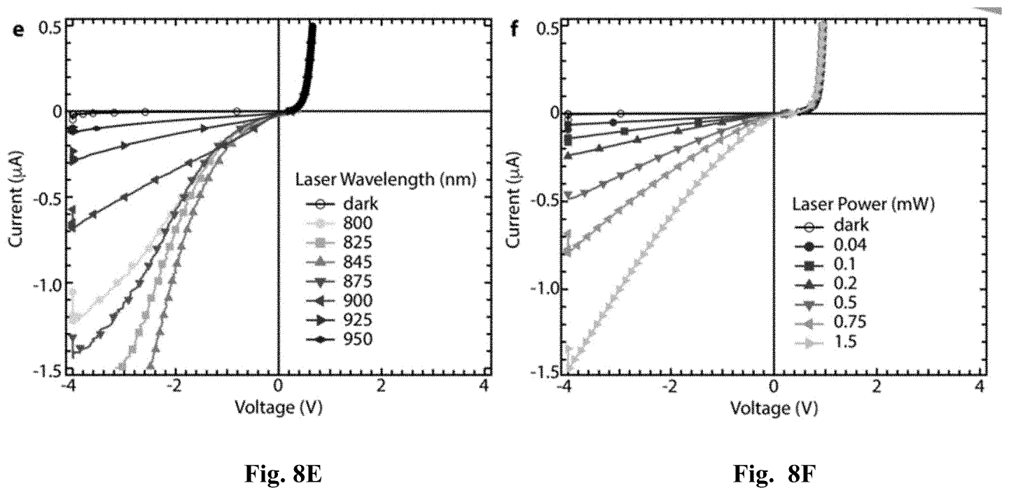

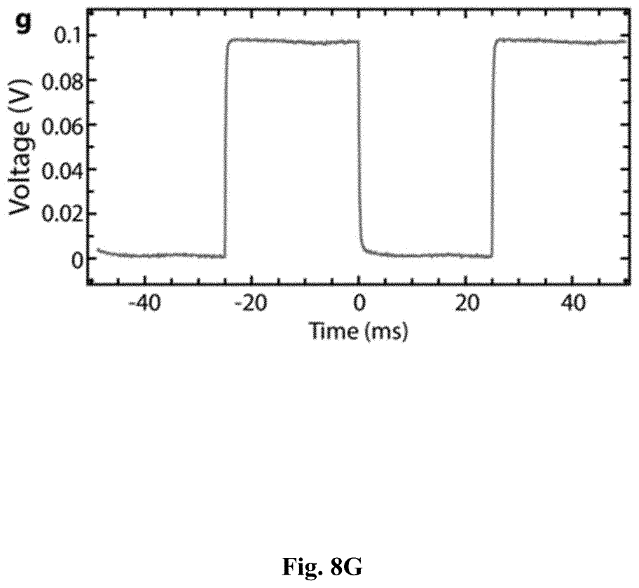

The p-B-n device consists of p-Zn₃As₂/CdTe/n-Cd₃As₂, with n-Cd₃As₂ acting as the light absorber and CdTe acting as an electron barrier. Like Cd₃As₂, Zn₃As₂ has a tetragonal crystal structure but a bandgap of 1.0 eV, making it a semiconductor. Our as-grown Zn₃As₂ epilayers have hole concentrations ˜1×10¹⁸ cm⁻³. Capacitance-voltage (C-V) measurements, detailed in the supplemental information, indicate this heterostructure has the flat-band alignment presented in FIG. 8A. Ideally, a p-B-n structure would have zero valence band offsets between all three layers to freely pass minority holes photogenerated in the n-Cd₃As₂ layer. However, undoped CdTe introduces a non-ideal valence band offset. Schematics of the basic behavior of this junction are presented in FIGS. 8B-8C. Given the higher carrier concentration and dielectric constant of Cd₃As₂ (6×10¹⁸ cm⁻³ and 36) compared to Zn₃As₂ (1×10¹⁸ cm⁻³ and 11), we expect the applied voltage to drop mainly over the CdTe and p-Zn₃As₂ semiconductor layers. Under relatively small forward bias, a current arises from majority hole flow from the p-Zn₃As₂ layer to the n-Cd₃As₂, while majority electrons in the Cd₃As₂ are blocked by the larger conduction band discontinuity at the n-Cd₃As₂/CdTe interface. In reverse bias, the majority hole current from the p-Zn₃As₂ is now suppressed by the electric field, leading to low dark currents in the device, even up to high applied reverse bias voltages. Minority holes photogenerated in the n-Cd₃As₂ layer, on the other hand, are driven by the electric field under reverse bias from the n-Cd₃As₂ to the p-Zn₃As₂ provided they can traverse the CdTe valence band barrier via thermionic emission or tunneling. Thus, a photocurrent can be generated over a wide reverse bias range (−1 to −4 V).

Experimentally, the described p-Zn₃As₂/CdTe/n-Cd₃As₂ p-B-n photodiode operates in exactly this manner. The device, schematically represented in FIG. 8D, was grown on an (001)-oriented ZnCdTe/GaAs substrate platform. The Zn₃As₂ has further been etched away from the regions between the front Au metal contacts such that light is incident directly on the CdTe layer. The room temperature dark current-voltage (I-V) curve of this device, shown in FIG. 8E, exhibits rectifying behavior, where the forward current increases sharply above 0.5 V, but the dark current in reverse bias remains below 0.003 mA out to at least −4 V. Light IV curves measured under 1 mW photoexcitation over a range of near infrared wavelengths, also displayed in FIG. 8E, exhibit a sizeable photoresponse in reverse bias. It is important to note that the ˜10 nm CdTe layer should not absorb photons with energies below its bandgap (1.48 eV, ˜840 nm), while it is thin enough to only weakly absorb photons with higher energies. Power-dependent IV curves measured with 900 nm excitation, displayed in FIG. 8F, show that the photocurrent increases roughly linearly with increasing laser power, indicating that trap state filling does not substantially change device performance in this current range. The photoresponse at 900 nm, shown in FIG. 8G, exhibits rise and fall times on the order of 200-300 ms.

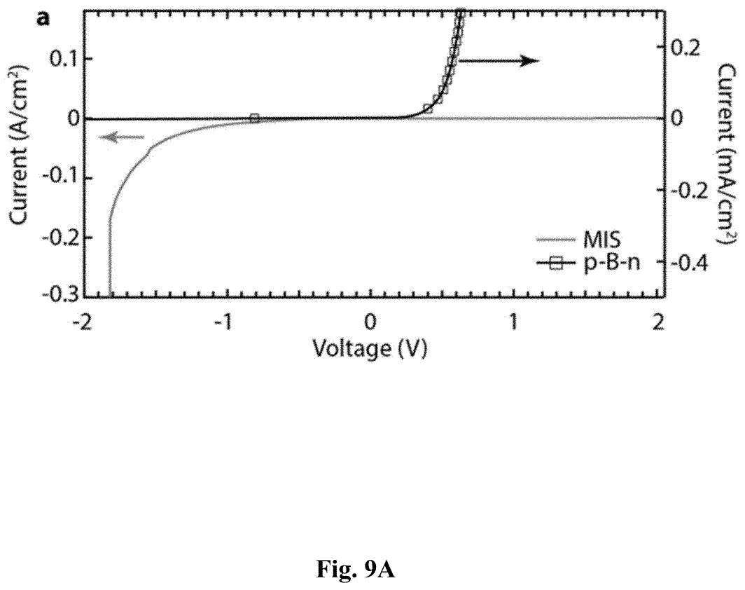

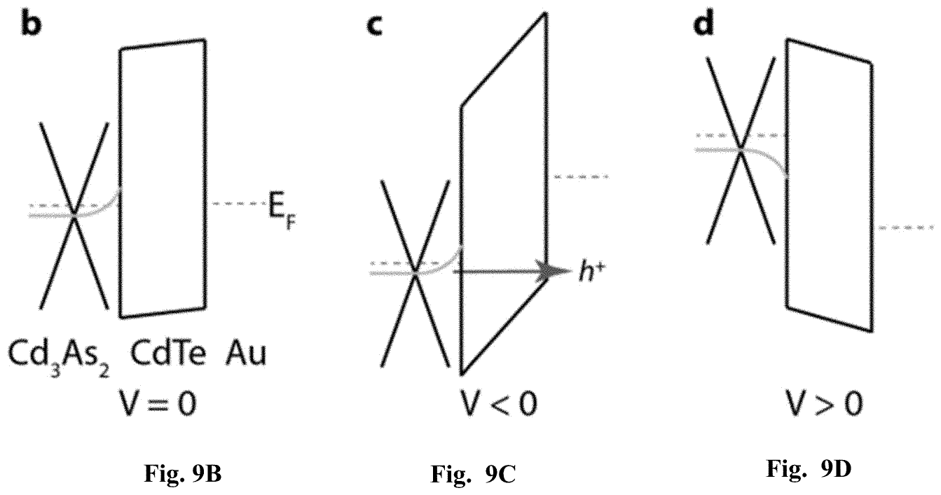

Interestingly, the p-Zn₃As₂ layer plays an important role in regulating the Fermi level in the Cd₃As₂ layer beyond its regular purpose in conventional semiconductor p-B-n diodes. One well known effect in graphene/semiconductor Schottky diodes is that a voltage drop in the graphene layer substantially shifts the Fermi level through the small density of states (DOS) near the Dirac node, leading to strong bias-dependent diode behavior. A similar effect is expected in a Cd₃As₂/semiconductor/metal junction in which the semiconductor layer is thin enough to not accommodate all of the voltage drop. To test whether this effect also arises in Cd₃As₂, we fabricated a photodiode with a similar structure to that in FIG. 8D but without the p-Zn₃As₂ layer, creating a Cd₃As₂/CdTe/Au metal-insulator-semiconductor (MIS) device. The dark IV curve, shown in FIG. 9A, is different than that of the p-B-n photodiode. Strikingly, the dark current increases substantially in reverse current. This behavior can be explained by band bending that is now present in the Cd₃As₂ layer and is caused by Fermi level alignment to Au at zero bias (FIG. 9B). The band bending persists in reverse bias, leading to transport of accumulated holes at the Cd₃As₂/CdTe interface through the CdTe layer and increasing dark current with increasing reverse bias (FIG. 9C). Finally, breakdown in the MIS structure occurs at low reverse biases below −2 V (FIG. 9A) because the Fermi level cannot be shifted higher into the conduction band in the quasi-neutral region of the bulk Cd₃As₂ layer, forcing additional voltage drop to occur across the CdTe. From this result, we extract a breakdown field within the CdTe layer of ˜6×10⁵ V/cm, which is comparable to the reported values in the literatures and further confirms the high quality of this thin heteroepitaxially-grown CdTe layer.

The comparatively low dark current in the p-B-n structure (also shown in FIG. 9A) suggest that much less voltage drops across the Cd₃As₂ in reverse bias when the p-Zn₃As₂ layer is present. Instead, that voltage drops across the p-Zn₃As₂ layer, preventing band bending and hole accumulation in the Cd₃As₂. Under reverse bias, where most photodiodes are operated, the p-Zn₃As₂ therefore performs the important additional task of stabilizing the Fermi level in the Cd₃As₂ conduction band and reducing the dark current.

### Discussion

The device we have demonstrated here is novel among Cd₃As₂-based photodetectors for three reasons. Primarily, it is the first all-epitaxial vertical heterojunction that is fundamentally capable of low dark currents when operated in reverse bias. This heterojunction is made possible by the ability to epitaxially grow thin, high-quality semiconductor layers on Cd₃As₂. Implementation of a p-B-n structure over other diode designs, like an MIS structure or simple Schottky junction, also introduces a mechanism to pin the Fermi level within the Cd₃As₂ conduction band under reverse bias and maintain low dark currents. Third, our use of the (001) crystallographic orientation to enable heteroepitaxy on Cd₃As₂ also allows these devices to be inherently fabricated on large area GaAs (001) substrates, making a leap to integration with more sophisticated devices fabricated with conventional manufacturing methods

The performance of this initial device is still far from ideal. Immediate opportunities for improving the responsivity include adding a transparent front contact for better collection of photogenerated carriers and an anti-reflective coating in cases where detection of specific wavelengths is targeted. A barrier material with a lower valence band offset with Cd₃As₂ will also improve the flow of minority photogenerated holes to the p-Zn₃As₂ layer. Quaternary (Hg, Cd, Zn)Te is one option for raising the valence band maximum without lowering the conduction band minimum substantially. Improving the ZnCdTe buffer to utilize a metamorphic graded layer structure designed to control threading dislocation densities in the Cd₃As₂ layer and replacing the CdTe insulator with a lattice-matched (Hg, Zn, Cd)Te epilayer could further reduce the overall number of defect states available for carrier recombination. However, this preliminary demonstration shows that a range of high performance devices are now possible with the ability to epitaxially grow thin semiconductors on Cd₃As₂.

### Methods

Epitaxy and device fabrication. Samples were grown in an interconnected system with dedicated III-V and II-VI chambers. Cd₃As₂ layers were grown from elemental Cd and As₄ sources. CdTe layers were grown from Cd and Te effusion cells with a 2:1 Te/Cd ratio. They were initially nucleated at a substrate temperature of 115° C. before slowly increasing the temperature to 175-240 C. Samples were annealed under As to 250° C. following growth. For device structures, Zn₃As₂ was then grown at this temperature with a 2:1 As/Zn ratio. Photodetectors and devices for CV measurements were fabricated with standard photolithography. Argon ion and wet chemical etching techniques were used to remove the telluride and arsenide layers, respectively. Au contacts were electroplated.

Characterization. Variable temperature Hall measurements were performed between 2-300 K in a Quantum Design Dynacool® Physical properties measurement system. A current of 0.1 mA and a magnetic field of +/−0.1 T were used. Current-voltage and capacitance-voltage measurements were carried out by the Keithely® 4200A-SCS parameter analyzer and all the frequency of the C-V measurement was fixed at 500 kHz.

Photodetector measurement. The photo-IV response was measured using a continuous wave laser focused to a 100-μm diameter spot over the front contact grid. Curves were acquired in current-source, voltage-sense mode. Temporal waveforms used 1-mW peak laser power that was square-wave modulated using an acousto-optic modulator. The detector bias was held at -1.5 V and the output was measured across a 470 kΩ load in parallel with a 1 MW oscilloscope.

The described invention may be further understood by the following non-limiting examples:
Example 1. A device comprising:
   a Dirac, Weyl or nodal line topological semimetal layer;
   a dielectric layer proximate to the semimetal layer;
   a metal layer or semiconductor layer proximate to the dielectric layer.
Example 2. The device of example 1 further comprising a substrate proximate to the semimetal layer or the metal layer.
Example 3. The device of example 1 or 2, wherein the Dirac, Weyl or nodal line semimetal layer comprises a semimetal selected from the group consisting of: Cd₃As₂, Na₃Bi, WTe₂, NbAs, TaAs, TaP, NbP, ZrTe₅, PtSe₂, α-Sn and a combination thereof.
Example 4. The device of any of examples 1-3, wherein the semimetal is layer comprises a Dirac semimetal.
Example 5. The device of any of examples 1-3, wherein the semimetal layer comprises a Weyl semimetal.
Example 6. The device of any of examples 1-3, wherein the semimetal layer comprises a nodal line semimetal.
Example 7. The device of any of examples 1-6, wherein the dielectric layer comprises a dielectric selected from the group consisting of: CdTe, ZnTe, ZnₓCd₁₋ₓTe, Al₂O₃, a III-V semiconductor, a II-VI semiconductor, an oxide, a nitride, a silicide and a combination thereof.
Example 8. The device of any of examples 1-7, wherein the dielectric layer is undoped.
Example 9. The device of any of examples 1-8 comprising a semiconductor layer proximate to the dielectric layer, wherein the device is a photodetector.
Example 10. The device of example 9, wherein the semiconductor layer comprises a semiconductor selected from the group consisting of: a III-V semiconductor, a II-VI semiconductor, a IV semiconductor, Cd₃P₃, Zn₃P₃, Zn₃As₂, Si, GaSb, GaAs and a combination thereof.
Example 11. The device of example 9 or 10, wherein the semiconductor layer is doped.
Example 12. The device of any examples 9-11 further comprising one or more electrical contacts.
Example 13. The device of any of examples 1-8 comprising a metal layer proximate to the dielectric layer, wherein the device is a transistor.
Example 14. The device of example 13, wherein the metal layer comprises at least two distinct metal portions.
Example 15. The device of example 13 or 14, wherein the metal layer comprises one or more metals selected from the group consisting of: Ti, Pt, Pd, Ag, Au, Al, In, Ni, W, Mo, Cu, Co and any combinations thereof.
Example 16. The device of example 15, wherein the metal layer is an alloy further comprising Si, Ge, Sb, N or a combination thereof.
Example 17. The device any of examples 13-16, wherein the metal layer induces doping in the semimetal layer.
Example 18. The device of any of examples 1-17, wherein the semimetal layer, the dielectric layer, the metal layer and/or the semiconductor layer are epitaxially integrated.
Example 19. A photodetector comprising:
   a semimetal layer comprising a Dirac, Weyl or nodal line topological semimetal selected from the group consisting of: Cd₃As₂, Na₃Bi, NbAs, WTe₂, TaAs, TaP, ZrTe₅, NbP and a combination thereof;
   an undoped dielectric layer proximate to the semimetal layer; and
   a doped semiconductor layer proximate to the dielectric layer;
   wherein the semimetal layer, the dielectric layer and/or the semiconductor layer are epitaxially integrated.
Example 20. A transistor comprising:
   a semimetal layer comprising a Dirac, Weyl or nodal line topological semimetal selected from the group consisting of: Cd₃As₂, Na₃Bi, NbAs, WTe₂, TaAs, TaP, ZrTe₅, NbP and a combination thereof;
   an undoped dielectric layer proximate to the semimetal layer; and
   a metal layer comprising at least one metal proximate to the dielectric layer;
   wherein the semimetal layer, the dielectric layer and/or the metal layer are epitaxially integrated.
Example 21. A method comprising:
   providing a Dirac, Weyl or nodal line topological semimetal layer substrate;
   growing a dielectric or semiconductor layer on a surface on the semimetal layer.
Example 22. The method of example 21, wherein the step of growing a dielectric or semiconductor layer is performed via molecular beam epitaxy.
Example 23. The method of example 21 or 22, wherein the semimetal layer comprises Cd₃As₂, Na₃Bi, NbAs, WTe₂, TaAs, TaP, ZrTe₅, NbP or a combination thereof.
Example 24. The method of any of examples 21-23, wherein the dielectric layer or semiconductor layer comprises CdTe, ZnTe, ZnₓCd₁₋ₓTe, Al₂O₃, a III-V semiconductor, a II-VI semiconductor, an oxide, a nitride, a silicide or a combination thereof.
Example 25. The method of any of examples 21-24 further comprising growing the Dirac, Weyl or nodal line topological semimetal layer on a GaAs, Si, Ge, GaSb, InSb, InAs, or InP substrate.

The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments, exemplary embodiments and optional features, modification and variation of the concepts herein disclosed may be resorted to by those skilled in the art, and that such modifications and variations are considered to be within the scope of this invention as defined by the appended claims. The specific embodiments provided herein are examples of useful embodiments of the present invention and it will be apparent to one skilled in the art that the present invention may be carried out using a large number of variations of the devices, device components, methods steps set forth in the present description. As will be obvious to one of skill in the art, methods and devices useful for the present methods can include a large number of optional composition and processing elements and steps.

As used herein and in the appended claims, the singular forms “a”, “an”, and “the” include plural reference unless the context clearly dictates otherwise. Thus, for example, reference to “a cell” includes a plurality of such cells and equivalents thereof known to those skilled in the art. As well, the terms “a” (or “an”), “one or more” and “at least one” can be used interchangeably herein. It is also to be noted that the terms “comprising”, “including”, and “having” can be used interchangeably. The expression “of any of claims XX-YY” (wherein XX and YY refer to claim numbers) is intended to provide a multiple dependent claim in the alternative form, and in some embodiments is interchangeable with the expression “as in any one of claims XX-YY.”

When a group of substituents is disclosed herein, it is understood that all individual members of that group and all subgroups, are disclosed separately. When a Markush group or other grouping is used herein, all individual members of the group and all combinations and subcombinations possible of the group are intended to be individually included in the disclosure. For example, when a device is set forth disclosing a range of materials, device components, and/or device configurations, the description is intended to include specific reference of each combination and/or variation corresponding to the disclosed range.

Every formulation or combination of components described or exemplified herein can be used to practice the invention, unless otherwise stated.

Whenever a range is given in the specification, for example, a density range, a number range, a temperature range, a time range, or a composition or concentration range, all intermediate ranges and subranges, as well as all individual values included in the ranges given are intended to be included in the disclosure. It will be understood that any subranges or individual values in a range or subrange that are included in the description herein can be excluded from the claims herein.

All patents and publications mentioned in the specification are indicative of the levels of skill of those skilled in the art to which the invention pertains. References cited herein are incorporated by reference herein in their entirety to indicate the state of the art as of their publication or filing date and it is intended that this information can be employed herein, if needed, to exclude specific embodiments that are in the prior art. For example, when composition of matter is claimed, it should be understood that compounds known and available in the art prior to Applicant's invention, including compounds for which an enabling disclosure is provided in the references cited herein, are not intended to be included in the composition of matter claims herein.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. In each instance herein any of the terms “comprising”, “consisting essentially of” and “consisting of” may be replaced with either of the other two terms. The invention illustratively described herein suitably may be practiced in the absence of any element or elements, limitation or limitations which is not specifically disclosed herein.

All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

What is claimed is:

1. A device comprising:
a Dirac, Weyl or nodal line topological semimetal layer;
a dielectric layer proximate to the semimetal layer;
a metal layer or semiconductor layer proximate to the dielectric layer.

2. The device of claim 1 further comprising a substrate proximate to the semimetal layer or the metal layer.

3. The device of claim 1, wherein the Dirac, Weyl or nodal line semimetal layer comprises a semimetal selected from the group consisting of: Cd₃As₂, Na₃Bi, WTe₂, NbAs, TaAs, TaP, NbP, ZrTe₅, PtSe₂, α-Sn and a combination thereof.

4. The device of claim 1, wherein the semimetal is layer comprises a Dirac semimetal.

5. The device of claim 1, wherein the semimetal layer comprises a Weyl semimetal.

6. The device of claim 1, wherein the semimetal layer comprises a nodal line semimetal.

7 The device of claim 1, wherein the dielectric layer comprises a dielectric selected from the group consisting of: CdTe, ZnTe, ZnₓCd₁₋ₓTe, Al₂O₃, a III-V semiconductor, a II-VI semiconductor, an oxide, a nitride, a silicide and a combination thereof.

8. The device of claim 1, wherein the dielectric layer is undoped.

9. The device of claim 1 comprising a semiconductor layer proximate to the dielectric layer, wherein the device is a photodetector.

10. The device of claim 9, wherein the semiconductor layer comprises a semiconductor selected from the group consisting of: a III-V semiconductor, a II-VI semiconductor, a IV semiconductor, Cd₃P₃, Zn₃P₃, Zn₃As₂, Si, GaSb, GaAs and a combination thereof

11. The device of claim 9, wherein the semiconductor layer is doped.

12. The device of claim 9 further comprising one or more electrical contacts.

13. The device of claim 1 further comprising a metal layer proximate to the dielectric layer, wherein the device is a transistor.

14. The device of claim 13, wherein the metal layer comprises at least two distinct metal portions.

15. The device of claim 13, wherein the metal layer comprises one or more metals selected from the group consisting of: Ti, Pt, Pd, Ag, Au, Al, In, Ni, W, Mo, Cu, Co and any combinations thereof.

16. The device of claim 15, wherein the metal layer is an alloy further comprising Si, Ge, Sb, N or a combination thereof.

17. The device claim 13, wherein the metal layer induces doping in the semimetal layer.

18. The device of claim 1, wherein the semimetal layer, the dielectric layer, the metal layer and/or the semiconductor layer are epitaxially integrated.

19. A photodetector comprising:
a semimetal layer comprising a Dirac, Weyl or nodal line topological semimetal selected from the group consisting of: Cd₃As₂, Na₃Bi, NbAs, WTe₂, TaAs, TaP, ZrTe₅, NbP and a combination thereof;
an undoped dielectric layer proximate to the semimetal layer; and
a doped semiconductor layer proximate to the dielectric layer;
wherein the semimetal layer, the dielectric layer and/or the semiconductor layer are epitaxially integrated.

20. A transistor comprising:
a semimetal layer comprising a Dirac, Weyl or nodal line topological semimetal selected from the group consisting of: Cd₃As₂, Na₃Bi, NbAs, WTe₂, TaAs, TaP, ZrTe₅, NbP and a combination thereof;
an undoped dielectric layer proximate to the semimetal layer; and
a metal layer comprising at least one metal proximate to the dielectric layer;
wherein the semimetal layer, the dielectric layer and/or the metal layer are epitaxially integrated.
